(19) United States
(12) Patent Application Publication
(10) Pub. No.: US 2018/0337026 A1
(43) Pub. Date: Nov. 22, 2018

(54) EROSION RESISTANT ATOMIC LAYER DEPOSITION COATINGS

(71) Applicant: Applied Materials, Inc., Santa Clara, CA (US)

(72) Inventors: Vahid Firouzdor, San Mateo, CA (US); Sumanth Banda, San Jose, CA (US); Dana Lovell, San Mateo, CA (US); Daniel Byun, Campbell, CA (US); Rajinder Dhindsa, Pleasanton, CA (US)

(21) Appl. No.: 15/982,632

(22) Filed: May 17, 2018

Related U.S. Application Data
(60) Provisional application No. 62/508,687, filed on May 19, 2017.

(51) Int. Cl. H01J 37/32; C23C 16/455; C23C 16/40; H01L 21/683; H01L 21/67

(52) U.S. Cl. CPC H01J 37/32715; C23C 16/45536; C23C 16/40; H01J 37/32724; H01L 21/67248; H01L 21/6833; H01L 21/67069; H01J 2237/002; H01J 2237/334; H01J 37/32807

(57) ABSTRACT

Described herein are articles, systems and methods where a plasma resistant coating is deposited onto a surface of a chamber component using an atomic layer deposition (ALD) process. The chamber component may include an insulator material with good electrical properties. The dielectric constant of a coated insulator material may be within about ±5% of the dielectric constant of the insulator material without the plasma resistant coating.

### TECHNICAL FIELD

Embodiments of the disclosure relate to articles, coated chamber components and methods of coating chamber components with a plasma resistant coating. The plasma resistant coating can include a high purity oxide layer that coats all surfaces of a component including insulator materials of the component. Optionally, the plasma resistant coating can include a rare-earth metal-containing oxide layer and/or an aluminum oxide layer. The coating is formed using a non-line of sight technique such as atomic layer deposition.

### BACKGROUND

Various manufacturing processes expose semiconductor process chamber components to high temperatures, high energy plasma, a mixture of corrosive gases, high stress, and combinations thereof. These extreme conditions may erode and/or corrode the chamber components, increasing the chamber components' susceptibility to defects. It is desirable to reduce these defects and improve the components' erosion and/or corrosion resistance in such extreme environments.

Protective coatings are typically deposited on chamber components by a variety of methods, such as thermal spray, sputtering, ion assisted deposition (IAD), plasma spray or evaporation techniques. These techniques generally cannot deposit thin, uniform coatings onto materials at a low deposition temperature or onto pore walls of pores within such chamber components. Additionally, these techniques are generally not suitable for coating substrate support assembly components such as insulator plates or for coating entire assemblies of multiple different components.

### SUMMARY

Described in embodiments herein is an article comprising a component comprising an insulator material with a dielectric constant of about 1.0 to about 10.0; and a plasma resistant coating on a surface of the insulator material, the plasma resistant coating having a thickness of about 5 nm to about 10 μm, wherein the plasma resistant coating protects the insulator material from erosion, and wherein the insulator material with the plasma resistant coating has the dielectric constant or an adjusted dielectric constant that is within about ±5% of the dielectric constant of the insulator material without the plasma resistant coating.

Further described in various embodiments herein is a method comprising performing atomic layer deposition (ALD) to deposit a plasma resistant coating on a component comprising an insulator material with a dielectric constant of about 1.0 to about 10.0, wherein the plasma resistant coating has a thickness of about 50 nm to about 5 μm, wherein the plasma resistant coating protects the insulator material from erosion, and wherein the insulator material with the plasma resistant coating has the dielectric constant or an adjusted dielectric constant that is within about ±5% of the dielectric constant of the insulator material without the plasma resistant coating.

In yet further various embodiments described herein is a substrate support assembly comprising an electrostatic puck comprising at least one through hole that extends from a top surface of the electrostatic puck to a bottom surface of the electrostatic puck, wherein the electrostatic puck has a first dielectric constant of about 1.0 to about 10.0; a porous plug in the at least one through hole; a cooling base bonded to the bottom surface of the electrostatic puck by a bond; and a first plasma resistant coating covering exposed surfaces of the electrostatic puck, the porous plug and the cooling base without covering unexposed portions of the electrostatic puck and the cooling base; wherein the first plasma resistant coating protects the substrate support assembly from erosion, and wherein the electrostatic puck with the first plasma resistant coating has the first dielectric constant or a first adjusted dielectric constant that is within about ±5% of the dielectric constant of the electrostatic puck without the first plasma resistant coating.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of a processing chamber.

FIG. 2A depicts a substrate support assembly where components have a plasma resistant coating in accordance with embodiments.

FIG. 2B depicts a substrate support assembly where all exposed surfaces have a plasma resistant coating in accordance with embodiments.

FIG. 2C depicts an exploded view of one embodiment of a substrate support assembly having a ceramic electrostatic puck to be coated as described herein.

FIG. 3A depicts one embodiment of a deposition process in accordance with an atomic layer deposition technique as described herein.

FIG. 3B depicts another embodiment of a deposition process in accordance with an atomic layer deposition technique as described herein.

FIG. 3C depicts another embodiment of a deposition process in accordance with an atomic layer deposition technique as described herein.

FIG. 3D depicts another embodiment of a deposition process in accordance with an atomic layer deposition technique as described herein.

FIG. 4A illustrates a method for creating a plasma resistant coating using atomic layer deposition as described herein.

FIG. 4B illustrates a method for creating a plasma resistant coating using atomic layer deposition as described herein.

FIG. 5 is a chart showing the etch rate of ALD Al₂O₃ coatings on a substrate when exposed to fluorine chemistry.

FIG. 6 is a chart showing the etch rate of a polysilicon coated substrate when exposed to a fluorine chemistry.

### DETAILED DESCRIPTION

Embodiments described herein cover articles, coated chamber components and methods where a plasma resistant coating is deposited onto insulator materials (e.g., polymers, ceramics, etc.) without substantially affecting the electrical properties (e.g., the dielectric constant) or other material properties of the insulator materials or onto pore walls of pores within the materials. The plasma resistant coating may be a high purity metal oxide layer (e.g., high purity aluminum oxide) or a rare earth metal-containing oxide layer (e.g., a yttrium-containing oxide layer). The plasma resistant coating may additionally be a multi-layer coating that includes one or more metal oxide layer as well as one or more rare earth metal-containing oxide layer. As used herein, the term plasma resistant means resistant to a plasma of at least one type of gas as well as chemistry and radicals of the at least one type of gas. The article may include a polymer (e.g., a crosslinked polystyrene) or a ceramic (e.g., aluminum oxide, silicon oxide, etc.) insulator material. The deposition process is a non-line of sight process such as an atomic layer deposition (ALD) process.

The thickness of the plasma resistant coating may be about 5 nm to about 10 μm, or about 50 nm to about 5 μm in some embodiments. The plasma resistant coating may conformally cover a surface of an insulator material of the chamber component and, in the case of a porous material, may also conformally cover the pore walls of the pores within the component with a substantially uniform thickness. In one embodiment, the dielectric constant of the insulator material coated with the plasma resistant coating is within ±5% of the dielectric constant of the insulator or ceramic material without the dielectric coating. In one embodiment, the dielectric constant of the coated insulator material is the same as the dielectric constant of the insulator ceramic material without the coating. In one embodiment, the plasma resistant coating has a conformal coverage of the underlying surface that is coated (including coated pore walls) with a uniform thickness having a thickness variation of less than ±20%, or a thickness variation of less than ±10%, or a thickness variation of less than ±5%, or a lower thickness variation.

Embodiments described herein protect insulator materials from corrosion in processing chambers when components containing these materials are exposed to plasmas. Certain components, for example, insulator plates for a substrate support assembly or an electrostatic chuck (ESC) and ceramics for an electrostatic puck, may contain materials selected for their advantageous electrical properties such as a low dielectric constant. Such insulator materials may not be resistant to plasma erosion when exposed to certain types of plasma within a processing chamber. Coating such insulator materials with a plasma resistant coating may protect the materials from plasma erosion. The coating, however, should not significantly affect the electrical properties (e.g., the dielectric constant) of the insulator materials so that the performance of the component is maintained. In accordance with embodiments herein, the coated insulator materials have a dielectric constant that is within ±5% of the dielectric constant of the materials without the coating. Additionally, the coating technique should be a non-line of sight process that can penetrate into the three-dimensional geometry of the components and cover all exposed internal and external surfaces.

Embodiments described herein also enable high aspect ratio features of an article such as pore walls within a porous ceramic body, for example, a porous ceramic puck for an ESC or such features of an insulator plate to be effectively coated with plasma resistant coatings. The porous ceramic body may be formed from a mixture of compounds such as (a) aluminum oxide (Al₂O₃) and aluminum silicon oxide (Al₂SiO₃), (b) Al₂O₃ and silicon dioxide (SiO₂), (c) Al₂O₃, magnesium oxide (MgO) and SiO₂ and so on. The compounds may have different etching kinetics such that one compound may corrode more quickly than another when exposed to aggressive etching chemistries. For example, if the ceramic material is a two phase material of Al₂O₃ and Al₂SiO₃, the Al₂O₃ rich phase may form the grains of the material and the Al₂SiO₃ may form the grain boundaries. Upon exposure to aggressive etch chemistries, the two phases will be corroded at different rates. For example, the Al₂SiO₃ grain boundary phase may etch away faster in fluorine containing chemistry which will result in loose grain boundaries and breaking of the Al₂O₃ grains. Such material failure may cause the ceramic body, for example, a ceramic puck, to break underneath the chucking force of a wafer. Eventually, the breakage may result in failure modes such as high backside particles, high helium leakage, degradation of temperature uniformity, high wear of the mesas and seal bands by wafer chucking, wafer breakage, reduction in chucking force, high metal contamination and even failure of an entire substrate support assembly (e.g., such as an ESC assembly). A plasma resistant coating on the entire ceramic body including within the pore walls of exposed pores (e.g., pores that are accessible to gases from the surface) may protect the body from erosion by corrosive gases within the processing chamber. The plasma resistant coating is also dense with a porosity of about 0% (e.g., the plasma resistant coating may be porosity-free in embodiments). The plasma resistant coatings may be resistant to corrosion and erosion from plasma etch chemistries, such as CCl₄/CHF₃ plasma etch chemistries, HCl₃Si etch chemistries and NF₃ etch chemistries.

ALD allows for a controlled self-limiting deposition of material through chemical reactions with the surface of the article. Aside from being a conformal process, ALD is also a uniform process and is capable of forming very thin films, for example, having a thickness of about 3 nm or more. All exposed sides of the article, including high aspect ratio features (e.g., about 3:1 to 300:1) will have the same or approximately the same amount of material deposited. As set forth herein, the coated insulator or ceramic material may have the same or substantially the same dielectric constant as the uncoated material. A typical reaction cycle of an ALD process starts with a precursor (i.e., a single chemical A) flooded into an ALD chamber and adsorbed onto surfaces of the article (including surfaces of pore walls within the article). The excess precursor is then flushed out of the ALD chamber before a reactant (i.e., a single chemical R) is introduced into the ALD chamber and subsequently flushed out. For ALD, the final thickness of material is dependent on the number of reaction cycles that are run, because each reaction cycle will grow a layer of a certain thickness that may be one atomic layer or a fraction of an atomic layer.

Unlike other techniques typically used to deposit coatings on components having insulator or ceramic materials, such as plasma spray coating and ion assisted deposition, the ALD technique can deposit a thin layer of material at a relatively low temperature (e.g., about 25° C. to about 200° C.) so that it does not damage or deform the component. For example, components such as an insulator plate that are composed of materials such as polystyrene may be damaged at temperatures above about 200° C. Additionally, The ALD technique, can also deposit a layer of material within porous materials (i.e., on the pore walls of the pores within a porous material). Additionally, the ALD technique generally produces relatively thin (i.e., 1 μm or less) coatings that are porosity-free (i.e., pin-hole free), which may eliminate crack formation during deposition. The surface of the porous component is coated in a manner that covers and plugs the pores and reduces or eliminates the permeability of the porous component.

Various process chamber components, such as insulator plates, ceramic pucks for an ESC, or an entire ESC assembly, would benefit from having plasma resistant coatings to protect the components in harsh etch environments while not impacting their performance. Conventional deposition methods can result in coatings that affect the electrical properties (e.g., dielectric constant) of the components and therefore impact their performance. Thus, an achievement of some embodiments is to apply a plasma resistant coating to the components' insulator materials without substantially affecting (e.g., no change or within ±5%) the electrical properties (e.g., the dielectric constant) of the materials. Applying, for example, an aluminum oxide coating to a component, such as an insulator plate, at a thickness of, for example, 0.5 μm-1 μm, may substantially improve the lifetime of the insulator plate and may increase the hardness of the material (e.g., for plates formed from plastics). Such coatings may also protect the surface from cracking. Additionally, insulator plates such as Rexolite plates are susceptible to erosion and to chemical attack, particularly by O₂ radicals. The plasma resistant coating protects the insulator plate from such chemical attack and greatly reduces erosion of the insulator plate. Additionally, a thin film aluminum oxide coating or other plasma resistant coating as discussed herein can act as an ultraviolet (UV) light blocker film and prevent high dose UV exposure of the component.

Moreover, polymeric material often used for insulator plates (e.g., Rexolite) outgases upon exposure to high temperature. Accordingly, deposition processes that use temperatures of over about 200° C. may cause the insulator plate to outgas during deposition. Such outgassing reduces an adhesion of the coating to the insulator plate.

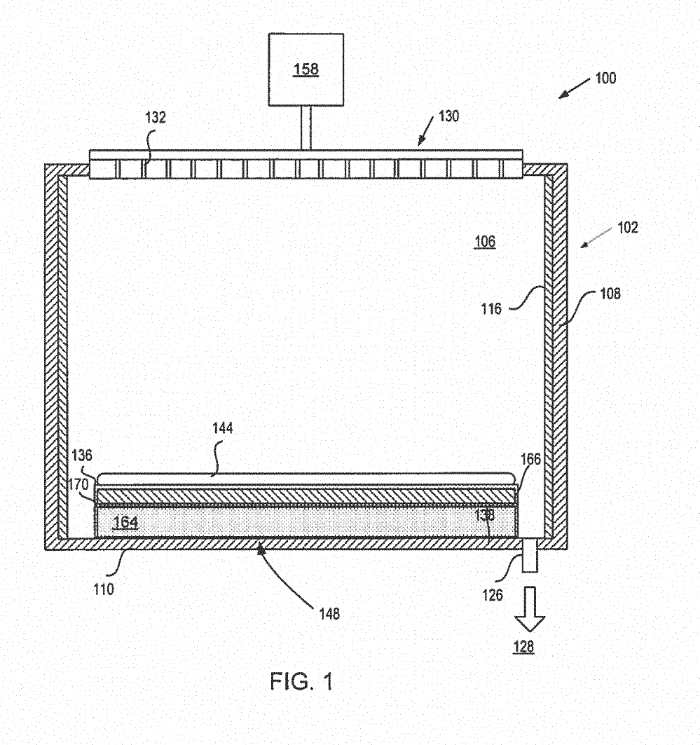

FIG. 1 is a sectional view of a semiconductor processing chamber 100 having one or more chamber components that are coated with a plasma resistant coating in accordance with embodiments. The processing chamber 100 may be used for processes in which a corrosive plasma environment having plasma processing conditions is provided. For example, the processing chamber 100 may be a chamber for a plasma etcher or plasma etch reactor, a plasma cleaner, plasma enhanced CVD or ALD reactors and so forth. Examples of chamber components that may include a plasma resistant coating is the insulator plate and the electrostatic puck of a substrate support assembly 148 such as an electrostatic chuck (ESC) assembly. The plasma resistant coating, which is described in greater detail below, is applied by ALD. ALD allows for the application of a conformal coating of a substantially uniform thickness that is porosity-free on all types of components including porous components with complex shapes and features having high aspect ratios.

The plasma resistant coating may be grown or deposited using ALD with a precursor for a metal oxide layer such as an aluminum-containing precursor. The plasma resistant coating may additionally or alternatively be grown or deposited using ALD with one or more precursors for deposition of a rare earth metal-containing oxide or co-deposition of a rare earth metal-containing oxide in combination with one or more additional oxides to form a rare earth metal-containing oxide layer. In one embodiment, the rare earth metal-containing oxide layer has a polycrystalline structure. Alternatively, the rare earth metal-containing oxide layer may have an amorphous structure. The rare earth metal-containing oxide may include yttrium, tantalum, zirconium and/or erbium. For example, the rare earth metal-containing oxide may be yttria (Y₂O₃), erbium oxide (Er₂O₃), zirconium oxide (ZrO₂), tantalum oxide (Ta₂O₅), and so on. In embodiments, the rare-earth metal-containing oxide is polycrystalline yttria. In other embodiments, the rare-earth metal-containing oxide is amorphous yttria. The rare earth metal-containing oxide may also include aluminum mixed with one or more rare earth elements such as yttrium, zirconium and/or erbium. The additional oxide (or oxides) that may be co-deposited with the rare earth metal-containing oxide to form the rare earth metal-containing oxide layer may include zirconium oxide (ZrO₂), aluminum oxide (Al₂O₃), erbium oxide (Er₂O₃), or a combination thereof. A yttrium-containing oxide layer for the multi-layer plasma resistant coating may be, for example, YₓZr_{y}O_{z}, YₐZrₓAl_{y}O_{z}, YₓAl_{y}O_{z}, or YₓEr_{y}O_{z}. The yttrium-containing oxide may be yttria (Y₂O₃) with yttriaite having a cubic structure with space group Ia-3 (206).

In one embodiment, the rare-earth metal-containing oxide layer is one of Y₂O₃, Er₂O₃, Y₃Al₅O₁₂ (YAG), Er₃Al₅O₁₂ (EAG), or Y₄Al₂O₉ (YAM). The rare-earth metal-containing oxide layer may also be YAlO₃ (YAP), Er₄Al₂O₉ (EAM), ErAlO₃ (EAP), a solid-solution of Y₂O₃—ZrO₂ and/or a ceramic compound comprising Y₄Al₂O₉ and a solid-solution of Y₂O₃—ZrO₂.

With reference to the solid-solution of Y₂O₃—ZrO₂, the rare-earth metal-containing oxide layer may include Y₂O₃ at a concentration of 10-90 molar ratio (mol %) and ZrO₂ at a concentration of 10-90 mol %. In some examples, the solid-solution of Y₂O₃—ZrO₂ may include 10-20 mol % Y₂O₃ and 80-90 mol % ZrO₂, may include 20-30 mol % Y₂O₃ and 70-80 mol % ZrO₂, may include 30-40 mol % Y₂O₃ and 60-70 mol % ZrO₂, may include 40-50 mol % Y₂O₃ and 50-60 mol % ZrO₂, may include 60-70 mol % Y₂O₃ and 30-40 mol % ZrO₂, may include 70-80 mol % Y₂O₃ and 20-30 mol % ZrO₂, may include 80-90 mol % Y₂O₃ and 10-20 mol % ZrO₂, and so on.

With reference to the ceramic compound comprising Y₄Al₂O₉ and a solid-solution of Y₂O₃—ZrO₂, in one embodiment the ceramic compound includes 62.93 molar ratio (mol %) Y₂O₃, 23.23 mol % ZrO₂ and 13.94 mol % Al₂O₃. In another embodiment, the ceramic compound can include Y₂O₃ in a range of 50-75 mol %, ZrO₂ in a range of 10-30 mol % and Al₂O₃ in a range of 10-30 mol %. In another embodiment, the ceramic compound can include Y₂O₃ in a range of 40-100 mol %, ZrO₂ in a range of 0.1-60 mol % and Al₂O₃ in a range of 0.1-10 mol %. In another embodiment, the ceramic compound can include Y₂O₃ in a range of 40-60 mol %, ZrO₂ in a range of 30-50 mol % and Al₂O₃ in a range of 10-20 mol %. In another embodiment, the ceramic compound can include Y₂O₃ in a range of 40-50 mol %, ZrO₂ in a range of 20-40 mol % and Al₂O₃ in a range of 20-40 mol %. In another embodiment, the ceramic compound can include Y₂O₃ in a range of 70-90 mol %, ZrO₂ in a range of 0.1-20 mol % and Al₂O₃ in a range of 10-20 mol %. In another embodiment, the ceramic compound can include Y₂O₃ in a range of 60-80 mol %, ZrO₂ in a range of 0.1-10 mol % and Al₂O₃ in a range of 20-40 mol %. In another embodiment, the ceramic compound can include Y₂O₃ in a range of 40-60 mol %, ZrO₂ in a range of 0.1-20 mol % and Al₂O₃ in a range of 30-40 mol %. In other embodiments, other distributions may also be used for the ceramic compound.

In one embodiment, an alternative ceramic compound that includes a combination of Y₂O₃, ZrO₂, Er₂O₃, Gd₂O₃ and SiO₂ is used for the rare-earth metal-containing oxide layer. In one embodiment, the alternative ceramic compound can include Y₂O₃ in a range of 40-45 mol %, ZrO₂ in a range of 0-10 mol %, Er₂O₃ in a range of 35-40 mol %, Gd2O3 in a range of 5-10 mol % and SiO2 in a range of 5-15 mol %. In a first example, the alternative ceramic compound includes 40 mol % Y₂O₃, 5 mol % ZrO₂, 35 mol % Er₂O₃, 5 mol % Gd₂O₃ and 15 mol % SiO₂. In a second example, the alternative ceramic compound includes 45 mol % Y₂O₃, 5 mol % ZrO₂, 35 mol % Er₂O₃, 10 mol % Gd₂O₃ and 5 mol % SiO₂. In a third example, the alternative ceramic compound includes 40 mol % Y₂O₃, 5 mol % ZrO₂, 40 mol % Er₂O₃, 7 mol % Gd₂O₃ and 8 mol % SiO₂.

Any of the aforementioned rare-earth metal-containing oxide layers may include trace amounts of other materials such as ZrO₂, Al₂O₃, SiO₂, B₂O₃, Er₂O₃, Nd₂O₃, Nb₂O₅, CeO₂, Sm₂O₃, Yb₂O₃, or other oxides.

The metal oxide layer may include high purity aluminum oxide or similar material that when used alone protects the component from plasma corrosion to at least some plasmas. It also improves adhesion of a rare-earth metal-containing oxide layer (when used) to the chamber component and provides thermal resistance to cracking and delamination of the plasma resistant coating at temperatures up to about 350° C. in embodiments or at about 200° C. or from about 200° C. to about 350° C.

In one embodiment, the processing chamber 100 includes a chamber body 102 and a showerhead 130 that enclose an interior volume 106. The showerhead 130 may include a showerhead base and a showerhead gas distribution plate. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110.

An outer liner 116 may be disposed adjacent the sidewalls 108 to protect the chamber body 102. The outer liner 116 may be fabricated and/or coated with a bi-layer coating. In one embodiment, the outer liner 116 is fabricated from aluminum oxide.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewall 108 of the chamber body 102. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 may include a gas distribution plate (GDP) and may have multiple gas delivery holes 132 throughout the GDP. The showerhead 130 may include the GDP bonded to an aluminum base or an anodized aluminum base. The GDP may be made from Si or SiC, or may be a ceramic such as Y₂O₃, Al₂O₃, Y₃Al₅O₁₂ (YAG), and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). A substrate support assembly 148 is disposed in the interior volume 106 of the processing chamber 100 below the showerhead 130 or lid. The substrate support assembly 148 holds a substrate 144 during processing.

An inner liner may be coated on the periphery of the substrate support assembly 148. The inner liner may be a halogen-containing gas resist material such as those discussed with reference to the outer liner 116. In one embodiment, the inner liner may be fabricated from the same materials of the outer liner 116.

In one embodiment, the substrate support assembly 148 is an ESC assembly that includes an electrostatic puck 166 bonded to a thermally conductive base called a cooling base 164 or cooling plate by a bond 138. The bond 138 may be a silicone bond in one embodiment. An o-ring 170 may be disposed around a region of the electrostatic puck 166 and the cooling base 164 at the interface of the electrostatic puck 166 and the cooling base 164. The o-ring 170 may protect the bond 138 from erosion and/or may provide a seal. An upper surface of the electrostatic puck 166 may be covered by the plasma resistant coating 136. Alternatively, all of the exposed portions of the substrate support assembly 148, including exposed portions of the electrostatic puck 166, the cooling plate 164, the o-ring 170, and so on. For example, the plasma resistant coating 136 may be disposed on the entire exposed surface of the ESC assembly including the outer and side periphery of the thermally conductive base 164 and the top and sides of the electrostatic puck 166 as well as any other exposed geometrically complex parts or holes having large aspect ratios in the electrostatic chuck assembly.

The cooling plate 164 and/or electrostatic puck 166 may include one or more optional embedded heating elements, embedded thermal isolators and/or conduits to control a lateral temperature profile of the substrate support assembly 148. The conduits may be fluidly coupled to a fluid source that circulates a temperature regulating fluid through the conduits. The embedded isolator may be disposed between the conduits in one embodiment. The heater is regulated by a heater power source. The conduits and heater may be utilized to control the temperature of the cooling plate 164. The conduits and heater heat and/or cool the electrostatic puck 166 and a substrate (e.g., a wafer) 144 being processed. The temperature of the electrostatic puck 166 and the cooling plate 164 may be monitored using a plurality of temperature sensors which may be monitored using a controller.

The electrostatic puck 166 may further include multiple gas passages such as grooves, mesas and other surface features that may be formed in an upper surface of the electrostatic puck 166. The gas passages may be fluidly coupled to a source of a heat transfer (or backside) gas such as He via holes drilled in the electrostatic puck 166. In operation, the backside gas may be provided at controlled pressure into the gas passages to enhance the heat transfer between the electrostatic puck 166 and the substrate 144. The He via holes may be plugged by porous ceramic plugs (not shown) that are permeable to the He. The porous ceramic plugs may also be at least partially permeable to corrosive gases and plasmas that are used to clean the semiconductor processing chamber 100. The porous ceramic plugs may filter gas particles of the corrosive gases and prevent such corrosive gases from penetrating into the substrate support assembly. The porous ceramic plugs may additionally prevent a secondary plasma from forming within the He vias in the electrostatic puck 166.

The electrostatic puck 166 includes at least one clamping electrode (not shown) controlled by a chucking power source. The clamping electrode (or other electrode disposed in the electrostatic puck 166 or cooling plate 164) may further be coupled to one or more RF power sources through a matching circuit for maintaining a plasma formed from process and/or other gases within the processing chamber 100.

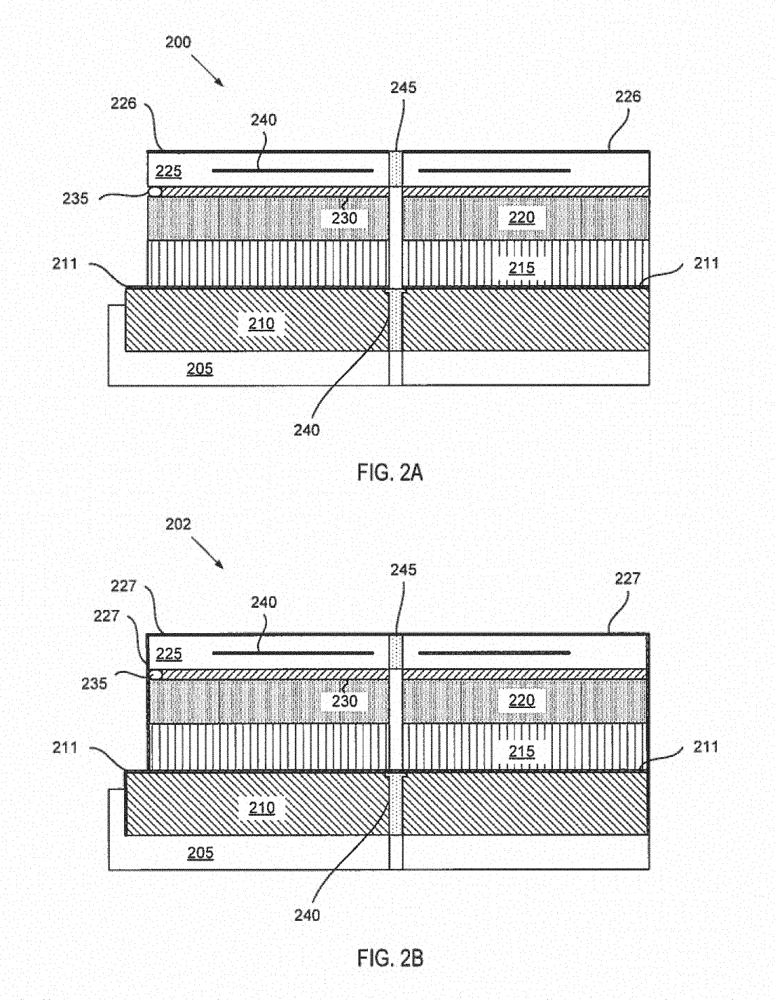

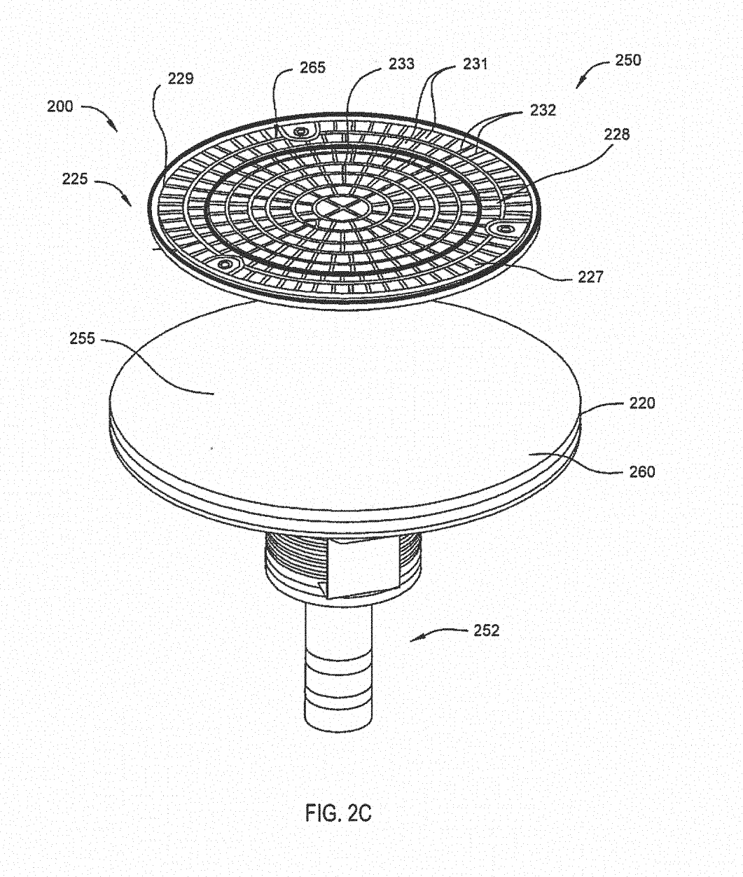

FIGS. 2A-C depict coated components of a substrate support assembly according to embodiments. FIG. 2A illustrates a substrate support assembly 200 that includes components that have been coated with a plasma resistant coating as described herein. The substrate support assembly 200 includes a mounting plate 205, an insulator plate 210, a facilities plate 215, and an electrostatic chuck assembly comprised of a thermally conductive base 220 and an electrostatic puck 225 bonded to the thermally conductive base 220 by a bond 230 such as a silicone bond. An o-ring 235 may be placed around the bond 230 at the periphery of the thermally conductive base 220 and electrostatic puck 225 to protect the bond 230. The o-ring 235 may be a fluoro-polymer compressible o-ring (e.g., a perfluoropolymer (PFP) or-ring) in embodiments. The electrostatic puck 225 may have a plasma resistant coating 226 on a surface thereof according to embodiments described herein. In one embodiment, the plasma resistant coating may be applied to the entire ESC assembly such that the thermally conductive base 220, electrostatic puck 225, bond 230 and o-ring 235 are all coated with a plasma resistant coating, as shown in FIG. 2B. In some embodiments, the plasma resistant coating may be applied to the thermally conductive base 220, electrostatic puck 225, and bond 230 before the o-ring 235 is installed. Accordingly, in some embodiments the o-ring 235 may not be coated with the plasma resistant coating.

The insulator plate 210 may be fabricated from a polymer material such as a crosslinked polystyrene (e.g., Rexolite®) or other material (e.g., Teflon®, aluminum oxide, etc.) having a dielectric constant of about 1 to about 10, or about 2 to about 5, or in the case of Rexolite® the dielectric constant may be about 2.53. Rexolite® is a microwave plastic manufactured by C-Lec Plastics®, Inc. It has stable electrical properties into the Giga-Hertz frequency range, for example, it has a dielectric constant of 2.53 (through 500 GHz) with extremely low dissipation factors. It is also optically clear, with a slight yellow cast (when polished), dimensionally stable and has excellent sound transmission characteristics. Although Rexolite® plastic is erosion resistant as compared to similar plastic materials, it still undergoes severe erosion damage in etch chambers which results in a change in the ESC performance, particle defects, chamber leakage and eventual cracking of the insulator plate. Besides direct plasma attack, polymer materials such as Rexolite® can also be damaged by exposure of high intensity ultraviolet (UV) light. Dry etch chamber systems use high doses of UV light which can break polymer chemical bonds resulting in material failure.

The insulator plate 210 may have a thickness of about 0.5 inch to about 1.5 inch or about 0.75 inch to about 1.25 inch or about 1 inch. The insulator plate 210 may provide electrical isolation from underneath grounded hardware (e.g., from the mounting plate 205). The insulator plate 210 has a plasma resistant coating 211 on a surface thereof that does not change the critical material properties of the insulator plate while also protecting against chemical radicals (e.g., O₂ and F₂ radicals) according to embodiments. The plasma resistant coating 211 may cover the entire surface of the insulator plate 210 or may cover only a portion of the surface. The substrate support assembly 200 may include one or more holes that penetrate the electrostatic puck 225, bond 230, thermally conductive base 220, facilities plate 215, insulator plate 210 and/or mounting plate 205. One or more porous ceramic plugs 240, 245 may be inserted into the holes to prevent corrosive gases and plasma from entering the through hole. The mounting plate 205 includes passages for routing utilities (e.g., fluids, power lines, sensor leads, etc.) to the thermally conductive base 220 and the electrostatic puck 225.

FIG. 2B illustrates a substrate support assembly 202 where all exposed surfaces of the components have been coated with a plasma resistant coating as described herein. As shown in FIG. 2B, the exposed surfaces of the insulator plate 210, the facilities plate 215, and the electrostatic chuck assembly comprised of the thermally conductive base 220 and the electrostatic puck 225 are coated with a plasma resistant coating 227 as described herein. Optionally, the o-ring 235 is also coated with the plasma resistant coating 227 as shown.

FIG. 2C depicts an exploded view of one embodiment of the substrate support assembly 200. The substrate support assembly 200 depicts an exploded view of the electrostatic chuck assembly 250 and the pedestal 252. The electrostatic chuck 250 includes the electrostatic puck 225 and the thermally conductive base 220 attached to the electrostatic puck 225. The electrostatic puck 225 has a disc-like shape having an annular periphery 227 that may substantially match the shape and size of a substrate positioned thereon. The electrostatic puck 225 may further include multiple gas passages such as grooves, mesas and other surface features that may be formed in an upper surface of the electrostatic puck 225. As shown in FIG. 2B, an upper surface 228 of the electrostatic puck 225 may have an outer ring 229, multiple mesas 231 and channels 232, 233 between the mesas. In one embodiment, the plasma resistant coating is disposed on the upper surface 265 of the electrostatic puck 225.

The gas passages may be fluidly coupled to a source of a heat transfer (or backside) gas such as He via the aforementioned holes. In operation, the backside gas may be provided at controlled pressure into the gas passages to enhance the heat transfer between the electrostatic puck 225 and a supported substrate. As stated above, the holes may be He via holes that are plugged by porous ceramic plugs 240, 245 that are permeable to the He. The porous ceramic plugs may also be at least partially permeable to corrosive gases and plasmas that are used to clean the semiconductor processing chamber. Porous ceramic plugs 240, 245 may filter gas particles of the corrosive gases and prevent such corrosive gases from penetrating into the substrate support assembly. The porous ceramic plugs 240, 245 may additionally prevent a secondary plasma from forming within the holes in the substrate support assembly 200.

The thermally conductive base 220 attached below the electrostatic puck 225 may have a disc-like main portion 255 and an annular flange 260 extending outwardly from a main portion 224 and positioned on the pedestal 252. The electrostatic puck 225 may be formed of a ceramic material or a metal ceramic material including an oxide, for example, an aluminum oxide, a silicon oxide, a magnesium oxide and so on. In some embodiments, the electrostatic puck 225 may be fabricated from a mixture of compounds, for example, Al₂O₃/Al₃SiO₂, Al₂O₃/SiO₂, Al₂O₃/MgO/SiO₂ and so on. The ceramic electrostatic puck 225 may have a dielectric constant of about 1 to about 10, or about 2 to about 9 or, about 8 to about 9. The thermally conductive base 220 may be fabricated by a material having thermal properties substantially matching that of the overlying puck 225. In one embodiment, the thermally conductive base 220 may be fabricated by a metal, such as aluminum or stainless steel or other suitable materials. Alternatively, the thermally conductive base 220 may be fabricated by a composite of ceramic and metal material providing good strength and durability as well as heat transfer properties. The composite material may have a thermal expansion coefficient that is substantially matched to the overlying puck 225 to reduce thermal expansion mismatch.

As shown in FIG. 2A, the electrostatic puck 225 includes at least one clamping electrode 240. The clamping electrode 240 (or other electrode disposed in the electrostatic puck 225) may further be coupled to one or more RF power sources through a matching circuit for maintaining a plasma formed from process and/or other gases within a processing chamber.

The porous ceramic plug 240 may be made from a ceramic material such as Al₂O₃/SiO₂, Al₂O₃/MgO/SiO₂, SiC, Si₃N₄, AlN/SiO₂ and the like. The ceramic plug 240 is an example porous ceramic chamber component whose performance may be improved by the use of the plasma resistant coating as set forth in embodiments herein. It is to be understood that the performance of other porous, ceramic chamber components may also be improved when coated with the plasma resistant coating disclosed herein. The ceramic plug 240, as depicted here, was chosen as an illustration of a semiconductor process chamber component having a surface with complex geometry and holes (i.e., pores) with high aspect ratios. Ceramic plug 240 may be exposed to corrosive chemistries such as fluorine and when not coated with a plasma resistant coating erodes due to plasma interaction with the plug.

Ceramic plug 240 has a plurality of pores. The ceramic plug 240 may have a porosity of about 5% to about 60%. The pores (and/or channels through the ceramic plug 240 formed by the pores) may have a high aspect ratio defined as the ratio of the length to diameter (L:D), where the high aspect ratio may range from about 3:1 to about 300:1, or about 50:1 to about 100:1. A surface of each pore can be coated with a plasma resistant coating as described herein.

The plasma resistant coating may comprise a high purity (HP) Al₂O₃ material or the like on a surface of each pore, which may be amorphous in embodiments. The purity of the HP-Al₂O₃ layer may be from about 89.99% to about 99.99% in some embodiments. The single-layer coating may have little or no impact on the flow path through each pore such that even with the single-layer coating, the pore is permeable to He gas during its normal operation. The plasma resistant coating may be grown or deposited on exterior surfaces of the ceramic plug 240 as well as on pore walls of pores within the ceramic plug 240 using the ALD technique.

The ALD technique enables a conformal coating of relatively uniform thickness and zero porosity (i.e., porosity-free) on the surfaces of chamber components and within features of the components including pores. The plasma resistant coating may reduce plasma interactions and improve a component's durability without impacting its performance. A thin plasma resistant coating deposited with ALD maintains the electrical properties and relative shape and geometric configuration of the component so as to not disturb its functionality. The coating may also provide plasma resistance and improve erosion and/or corrosion resistance to the interior of porous articles.

The resistance of the plasma resistant coating to plasma is measured through “etch rate” (ER), which may have units of micron/hour (μm/hr) or Angstrom/hour (Å/hr), throughout the duration of the coated components' operation and exposure to plasma. Measurements may be taken after different processing times. For example, measurements may be taken before processing, or at about 50 processing hours, or at about 150 processing hours, or at about 200 processing hours, and so on. Variations in the composition of the plasma resistant coating grown or deposited on the ESC plug or on any other process chamber component may result in multiple different plasma resistances or erosion rate values. Additionally, a plasma resistant coating with a single composition exposed to various plasmas could have multiple different plasma resistances or erosion rate values. For example, a plasma resistant material may have a first plasma resistance or erosion rate associated with a first type of plasma and a second plasma resistance or erosion rate associated with a second type of plasma.

In some embodiments, as will be discussed in more detail below, the plasma resistant coating may comprise a first layer and optionally a second rare-earth metal-containing oxide layer on top of the first layer (not shown). The first layer may comprise HP-Al₂O₃ and when a rare-earth metal-containing oxide layer is present, the first layer may comprise an amorphous HP-Al₂O₃ layer. The rare earth metal-containing oxide layer may comprise a yttrium oxide alone or together with an additional rare earth metal oxide (e.g., erbium oxide, zirconium oxide, etc.). The rare earth metal-containing oxide layer may have any rare earth metal-containing oxide material such as those described herein above. Each layer may be coated using an ALD process. The ALD process may grow conformal coating layers of uniform thickness that are thin and porosity-free and that do not substantially affect the electrical properties of the component.

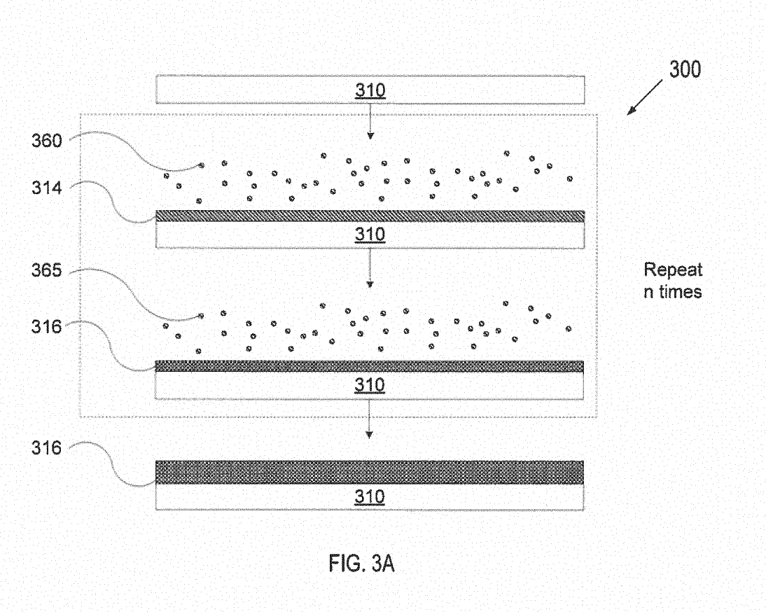

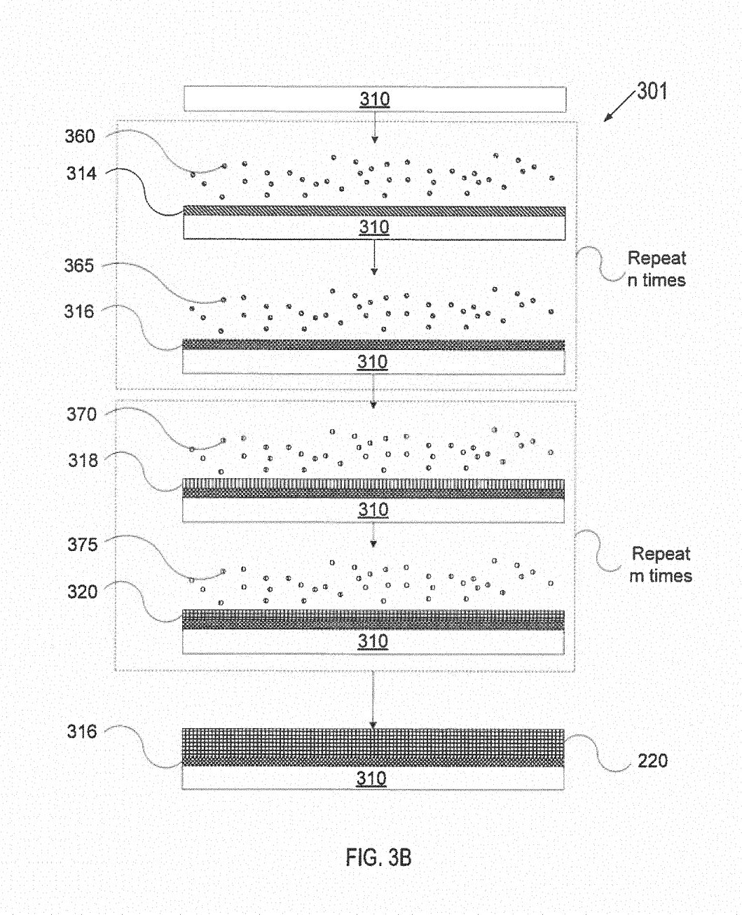

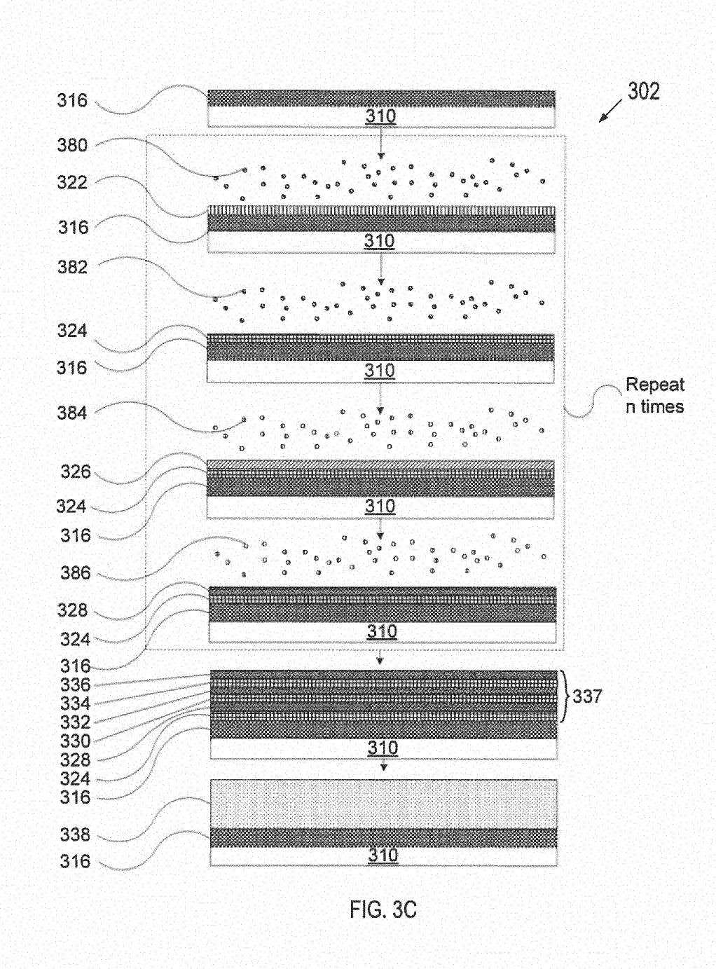

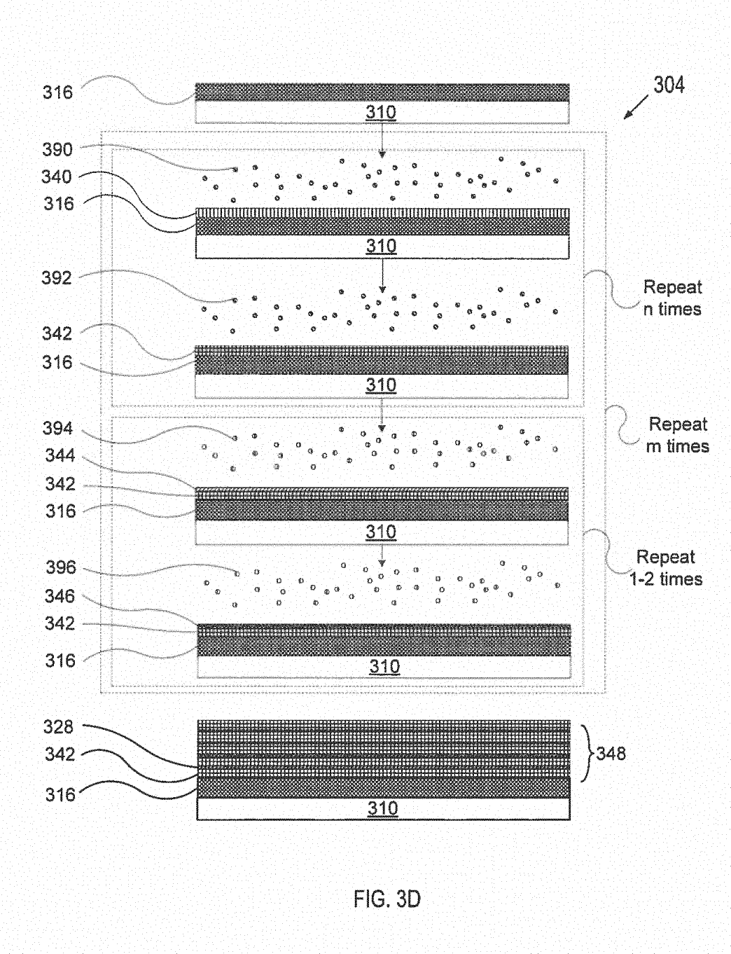

FIG. 3A depicts one embodiment of a deposition process in accordance with an ALD technique to grow or deposit a plasma resistant coating on an article (including on an insulator material of a component and pore walls within a porous material). FIG. 3B depicts one embodiment of a deposition process in accordance with an ALD technique to grow or deposit a multi-layer plasma resistant coating on an article (including on an insulator material of a component and pore walls within a porous material). FIG. 3C depicts another embodiment of a deposition process in accordance with an atomic layer deposition technique as described herein. FIG. 3D depicts another embodiment of a deposition process in accordance with an atomic layer deposition technique as described herein.

Various types of ALD processes exist and the specific type may be selected based on several factors such as the surface to be coated, the coating material, chemical interaction between the surface and the coating material, etc. The general principle for the various ALD processes comprises growing a thin film layer by repeatedly exposing the surface to be coated to pulses of gaseous chemical precursors that chemically react with the surface one at a time in a self-limiting manner.

FIGS. 3A-3D illustrate an article 310 having a surface. Article 310 may represent various insulator materials of semiconductor process chamber components including but not limited to an insulator plate, an electrostatic puck, and an entire ESC assembly. The article 310 may be made from a dielectric material such as a ceramic, a metal-ceramic composite (such as Al₂O₃/SiO₂, Al₂O₃/MgO/SiO₂, SiC, Si₃N₄, AlN/SiO₂ and the like), a metal (such as aluminum, stainless steel), or a polymer such as a crosslinked polystyrene (e.g., Rexolite®) or a polymer ceramic composite, mylar, polyester, or other suitable materials, and may further comprise materials such as MN, Si, SiC, Al₂O₃, SiO₂, and so on. In one embodiment, the article 310 is an insulator plate of a substrate support assembly that is composed of a crosslinked polystyrene material with a dielectric constant of about 2.0 to 5.0 or about 2.0 to 3.5 or about 2.3. In one embodiment, the article 310 is an electrostatic puck fabricated from a metal-ceramic composite (such as Al₂O₃/SiO₂, Al₂O₃/MgO/SiO₂, SiC, Si₃N₄, AlN/SiO₂ and the like). Such materials are susceptible to etching by fluorinating chemistry which can result in breaking the porous matrix and generation of particulates and metals.

For ALD, either adsorption of a precursor onto a surface or a reaction of a reactant with the adsorbed precursor may be referred to as a “half-reaction.” During a first half reaction, a precursor is pulsed onto the surface of the article 310 (including onto a surface of pore walls within the article 310) for a period of time sufficient to allow the precursor to fully adsorb onto the surface. The adsorption is self-limiting as the precursor will adsorb onto a finite number of available sites on the surface, forming a uniform continuous adsorption layer on the surface. Any sites that have already adsorbed with a precursor will become unavailable for further adsorption with the same precursor unless and/or until the adsorbed sites are subjected to a treatment that will form new available sites on the uniform continuous coating. Exemplary treatments may be plasma treatment, treatment by exposing the uniform continuous adsorption layer to radicals, or introduction of a different precursor able to react with the most recent uniform continuous layer adsorbed to the surface.

In some embodiments, two or more precursors are injected together and adsorbed onto the surface of an article. The excess precursors are pumped out until an oxygen-containing reactant is injected to react with the adsorbates to form a solid single phase or multi-phase layer (e.g., of YAG, a phase of Y₂O₃—ZrO₂, and so on). This fresh layer is ready to adsorb the precursors in the next cycle.

In FIG. 3A, article 310 may be introduced to a first precursor 360 for a first duration until a surface of article 310 is fully adsorbed with the first precursor 360 to form an adsorption layer 314. Subsequently, article 310 may be introduced to a first reactant 365 to react with the adsorption layer 314 to grow a solid layer 316 (e.g., so that the layer 316 is fully grown or deposited, where the terms grown and deposited may be used interchangeably herein). The first precursor 360 may be a precursor for a high purity metal oxide, for example, high purity aluminum oxide. The first reactant 365 may be oxygen, water vapor, ozone, pure oxygen, oxygen radicals, or another oxygen source if the layer 316 is an oxide. Accordingly, ALD may be used to form the layer 316. The layer 316 may be a plasma resistant coating, or may be one layer of a multi-layer plasma resistant coating.

In an example where the layer 316 is a high purity alumina (HP-Al₂O₃) layer, article 310 (e.g., an insulator plate, an electrostatic puck, an entire ESC assembly, etc.) may be introduced to a first precursor 360 (e.g., trimethyl aluminum (TMA)) for a first duration until all the reactive sites on the article's surfaces (including inside the pores) are consumed. The remaining first precursor 360 is flushed away and then a first reactant 365 of H₂O is injected into the reactor to start the second half cycle. A layer 316 of HP-Al₂O₃ is formed after H₂O molecules react with the Al containing adsorption layer created by the first half reaction.

Layer 316 may be uniform, continuous and conformal. Layer 316 may be porosity free (e.g., have a porosity of zero) or have an approximately zero porosity in embodiments (e.g., a porosity of 0% to 0.01%). Layer 316 may have a thickness of less than one atomic layer to a few atoms in some embodiments after a single ALD deposition cycle. Some metalorganic precursor molecules are large. After reacting with the reactant 365, large organic ligands may be gone, leaving much smaller metal atoms. One full ALD cycle (e.g., that includes introduction of precursors 360 followed by introduction of reactants 365) may result in less than a single atomic layer. For example, an Al₂O₃ monolayer grown by TMA and H₂O typically has a growth rate of about 0.9 A/cycle to about 1.3 A/cycle while the Al₂O₃ lattice constant is a-4.7 A and c=13 A (for a trigonal structure).

Multiple full ALD deposition cycles may be implemented to deposit a thicker layer 316, with each full cycle (e.g., including introducing precursor 360, flushing, introducing reactant 365, and again flushing) adding to the thickness by an additional fraction of an atom to a few atoms. As shown, up to n full cycles may be performed to grow the layer 316, where n is an integer value greater than 1. In embodiments, layer 316 may have a thickness of about 5 nm to about 3 μm. In a further embodiment, layer 316 has a thickness of about 5 nm to about 300 nm. Layer 316 may have a thickness of about 10 nm to about 150 nm in embodiments or about 50 nm to about 100 nm in other embodiments.

The layer 316 provides robust plasma resistance and mechanical properties. Layer 316 may protect the component from corrosion, enhance or maintain dielectric strength, provide better adhesion of a rare-earth metal-containing oxide layer to the component (e.g., formed of porous ceramic or A16061, A16063), and may prevent cracking of the plasma resistant coating at temperatures up to about 200° C., or up to about 250° C., or from about 200° C. to about 250° C. In further embodiments, the layer 316 may prevent cracking of the plasma resistant coating at temperatures of up to about 350° C. Since ALD is used for the deposition, the internal surfaces of high aspect ratio features such as gas delivery holes in a showerhead or pores in a porous material may be coated, and thus an entirety of a component may be protected from exposure to a corrosive environment.

Layer 316 may be HP-Al₂O₃, having a purity of about 89.99% to about 99.99%, in embodiments. High purity Al₂O₃ is significantly more resistant to plasma corrosion than typical polymers used for insulator plates and ceramic materials used for electrostatic chucks. Moreover, HP-Al₂O₃ has good adhesion to polymer, ceramic and aluminum based components because of common elements (e.g., aluminum and oxygen). Similarly, HP-Al₂O₃ has good adhesion to rare earth metal-containing oxides also because of common elements (i.e., the oxides). These improved interfaces reduce interfacial defects which are prone to initiate cracks.

FIG. 3B describes a deposition process 301 that includes the deposition of layer 316 as described with reference to FIG. 3A. However, the deposition process 301 of FIG. 3B further includes deposition of an additional layer 320 to form a multi-layer plasma resistant coating. Accordingly, after layer 316 is complete, article 310 having layer 316 optionally, may be introduced to an additional one or more precursors 370 for a second duration until layer 316 is fully adsorbed with the one or more additional precursors 370 to form an adsorption layer 318. Subsequently, article 310 may be introduced to a reactant 375 to react with adsorption layer 318 to grow a solid rare-earth metal-containing oxide layer 320, also referred to as the second layer 320 for simplicity (e.g., so that the second layer 320 is fully grown or deposited). In this embodiment, layer 316 may be an amorphous metal oxide (e.g., amorphous HP-Al₂O₃). Accordingly, the second layer 320 is fully grown or deposited over layer 316 using ALD. In an example, precursor 370 may be a yttrium containing precursor used in the first half cycle, and reactant 375 may be H₂O used in the second half cycle.

The second layer 320 may form an optional yttrium-containing oxide layer or other rare-earth metal-containing oxide layer, which may be uniform, continuous and conformal. The second layer 320 may have a very low porosity of less than 1% in embodiments, and less than 0.1% in further embodiments, and about 0% in embodiments or porosity-free in still further embodiments. Second layer 220 may have a thickness of less than an atom to a few atoms (e.g., 2-3 atoms) after a single full ALD deposition cycle. Multiple ALD deposition stages may be implemented to deposit a thicker second layer 320, with each stage adding to the thickness by an additional fraction of an atom to a few atoms. As shown, the full deposition cycle may be repeated m times to cause the second layer 320 to have a target thickness, where m is an integer value greater than 1. In embodiments, second layer 320 may have a thickness of about 5 nm to about 3 μm. In other embodiments, second layer 320 may have a thickness of about 5 nm to about 300 nm. Second layer 320 may have a thickness of about 10 nm to about 20 nm in embodiments or about 50 nm to about 60 nm in some embodiments. In other embodiments, second layer 320 may have a thickness of about 90 nm to about 110 nm.

A ratio of the second layer 320 thickness to the layer 316 thickness may be 200:1 to 1:200. A higher ratio of the second layer 320 thickness to the layer 316 thickness (e.g., 200:1, 100:1, 50:1, 20:1, 10:1, 5:1, 2:1 etc.) provides better corrosion and erosion resistance, while a lower ratio of the second layer 320 thickness to the layer 316 thickness (e.g., 1:2, 1:5, 1:10, 1:20, 1:50, 1:100, 1:200) provides better heat resistance (e.g., improved resistance to cracking and/or delamination caused by thermal cycling).

Second layer 320 may be any of the aforementioned rare-earth metal-containing oxide layers. For example, second layer 320 may be Y₂O₃, alone or in combination with one or more other rare earth metal oxides. In some embodiments, second layer 320 is a single phase material formed from a mixture of at least two rare earth metal-containing oxide precursors that have been co-deposited by ALD (e.g., combinations of one or more of Y₂O₃, Er₂O₃, Al₂O₃ and ZrO₂). For example, second layer 320 may be one of YₓZr_{y}O_{z}, YₓEr_{y}O_{z}, Y₃Al₅O₁₂ (YAG), Y₄Al₂O₉ (YAM), Y₂O₃ stabilized ZrO₂ (YSZ), or a ceramic compound comprising Y₄Al₂O₉ and a solid-solution of Y₂O₃—ZrO₂. In one embodiment, the layer 316 is amorphous HP-Al₂O₃ and the second layer 320 is a polycrystalline or amorphous yttrium-containing oxide compound (e.g., Y₂O₃, YₓAl_{y}O_{z}, YₓZr_{y}O_{z}, YₓEr_{y}O_{z}) alone or in a single phase with one or more other rare earth metal-containing oxide material. Accordingly, layer 316 may be a stress relief layer that is deposited prior to deposition of the yttrium-containing oxide layer.

In some embodiments, second layer 320 may include Er₂O₃, Y₂O₃, Al₂O₃, or ZrO₂. In some embodiments, second layer 320 is a multi-component material of at least one of ErₓAl_{y}O_{z} (e.g., Er₃Al₅O₁₂), ErₓZr_{y}O_{z}, ErₐZrₓAl_{y}O_{z}, YₓEr_{y}O_{z}, or ErₐYₓZr_{y}O_{z} (e.g., a single phase solid solution of Y₂O₃, ZrO₂ and Er₂O₃). Second layer 320 may also be one of Y₃Al₅O₁₂ (YAG), Y₄Al₂O₉ (YAM), Y₂O₃ stabilized ZrO₂ (YSZ), or a ceramic compound comprising Y₄Al₂O₉ and a solid-solution of Y₂O₃—ZrO₂. In one embodiment, the second layer 320 is an erbium containing compound (e.g., Er₂O₃, ErₓAl_{y}O_{z}, ErₓZr_{y}O_{z}, ErₐZrₓAl_{y}O_{z}, YₓEr_{y}O_{z}, or ErₐYₓZr_{y}O_{z}).

With reference to FIGS. 3C-3D, in some embodiments, the plasma resistant coating contains more than two layers. Specifically, the plasma resistant coating may include a sequence of alternating layers of an oxide layer and the rare-earth metal-containing oxide layer, or may include the layer 316 and a sequence of alternating layers for the rare-earth metal-containing oxide layer. In some embodiments, a rare-earth metal-containing oxide layer is a layer of alternating sub-layers. For example, a rare-earth metal-containing oxide layer may be a series of alternating sublayers of Y₂O₃ and Al₂O₃, a series of alternating sublayers of Y₂O₃ and ZrO₂, a series of alternating sublayers of Y₂O₃, Al₂O₃ and ZrO₂, and so on.

Referring to FIG. 3C, an article 310 having a layer 316 may be inserted into a deposition chamber. The layer 316 may have been formed as set forth with reference to FIG. 3A or FIG. 3B. Alternatively, an article 310 without a layer formed thereon may be provided. Article 310 may be introduced to one or more precursors 380 for a duration until the layer 316 or article 310 is fully adsorbed with the one or more additional precursors 380 to form an adsorption layer 322. Subsequently, article 310 may be introduced to a reactant 382 to react with adsorption layer 322 to grow a solid metal oxide layer 324. Accordingly, the metal oxide layer 324 is fully grown or deposited over layer 316 using ALD. In an example, precursor 380 may be a yttrium containing precursor used in the first half cycle, and reactant 382 may be H₂O used in the second half cycle. The metal oxide layer 324 may be a first one of Y₂O₃, ZrO₂, Al₂O₃, Er₂O₃, Ta₂O₅, or another oxide.

Article 310 having layer 316 and/or metal oxide layer 324 may be introduced to one or more precursors 384 for a duration until a surface of metal oxide layer 324 is fully adsorbed with the one or more precursors 384 to form an adsorption layer 326. Subsequently, article 310 may be introduced to a reactant 386 to react with adsorption layer 326 to grow an additional solid metal oxide layer 328. Accordingly, the additional metal oxide layer 328 is fully grown or deposited over the metal oxide layer 324 using ALD. In an example, precursor 384 may be a zirconium containing precursor used in the first half cycle, and reactant 386 may be H₂O used in the second half cycle. The metal oxide layer 324 may be a second one of Y₂O₃, ZrO₂, Al₂O₃, Er₂O₃, Ta₂O₅, or another oxide.

As shown, the deposition of the metal oxide 324 and the second metal oxide 328 may be repeated n times to form a stack 337 of alternating layers, where n is an integer value greater than 2. N may represent a finite number of layers selected based on the targeted thickness and properties. The stack 337 of alternating layers may be considered as a rare-earth metal-containing oxide layer containing multiple alternating sub-layers. Accordingly, precursors 380, reactants 384, precursors 384 and reactants 386 may be repeatedly introduced sequentially to grow or deposit additional alternating layers 330, 332, 334, 336, and so on. Each of the layers 324, 324, 330, 332, 334, 336, and so on may be very thin layers having a thickness of less than a single atomic layer to a few atomic layers. For example, an Al₂O₃ monolayer grown by TMA and H₂O typically has a growth rate of about 0.9 to about 0.3 A/cycle while the Al₂O₃ lattice constant is a-4.7 A and c=13 A (for a trigonal structure).

The alternating layers 324-336 described above have a 1:1 ratio, where there is a single layer of a first metal oxide for each single layer of a second metal oxide. However, in other embodiments there may be other ratios such as 2:1, 3:1, 4:1, and so on between the different types of metal oxide layers. For example, two Y₂O₃ layers may be deposited for every ZrO₂ layer in an embodiment. Additionally, the stack 337 of alternating layers 324-336 have been described as an alternating series of two types of metal oxide layers. However, in other embodiments more than two types of metal oxide layers may be deposited in an alternating stack 337. For example, the stack 337 may include three different alternating layers (e.g., a first layer of Y₂O₃, a first layer of Al₂O₃, a first layer of ZrO₂, a second layer of Y₂O₃, a second layer of Al₂O₃, a second layer of ZrO₂, and so on).

After the stack 337 of alternating layers has been formed, an anneal process may be performed to cause the alternating layers of different materials to diffuse into one another and form a complex oxide having a single phase or multiple phases. After the annealing process, the stack of alternating layers 337 may therefore become a single rare-earth metal-containing oxide layer 338. For example, if the layers in the stack are Y₂O₃, Al₂O₃, and ZrO₂, then the resulting rare-earth metal-containing oxide layer 338 may a ceramic compound comprising Y₄Al₂O₉ and a solid-solution of Y₂O₃—ZrO₂. If the layers in the stack are Y₂O₃ and ZrO₂, then be a solid-solution of Y₂O₃—ZrO₂ may be formed.

Referring to FIG. 3D, an article 310 having a layer 316 may be inserted into a deposition chamber. Alternatively, an article 310 without such a layer 316 may be inserted into the deposition chamber. The layer 316 may have been formed as set forth with reference to FIG. 3A or FIG. 3B. Article 310 may be introduced to one or more precursors 390 for a duration until layer 316 or article 310 is fully adsorbed with the one or more precursors 390 to form an adsorption layer 340. Subsequently, article 310 may be introduced to a reactant 392 to react with adsorption layer 340 to grow a solid rare earth oxide layer 342. The precursors 390 and reactant 392 may correspond to precursors 370 and reactant 375 in embodiments. Accordingly, the rare earth oxide layer 342 is fully grown or deposited over layer 316 using ALD. The process of introducing the precursors 390 and then the reactant 392 may be repeated n times to cause the rare earth oxide layer 342 to have a target thickness, where n is an integer greater than 1.

Article 310 having layer 316 and/or rare earth oxide layer 342 may be introduced to one or more precursors 394 for a duration until a surface of rare earth oxide layer 342 is fully adsorbed with the one or more precursors 394 to form an adsorption layer 344. Subsequently, article 310 may be introduced to a reactant 396 to react with adsorption layer 344 to grow a barrier layer 346. The precursors 394 and reactants 396 may correspond to precursors 360 and reactants 365 in embodiments. Accordingly, the barrier layer 344 may have a same material composition as the surface layer 316. The barrier layer 346 is fully grown or deposited over the rare earth oxide layer 342 using ALD. The process of introducing the precursors 394 and then the reactant 396 may be performed one or two times to form a thin barrier layer 346 that may prevent crystal growth in the rare earth oxide layers.

As shown, the deposition of the rare earth oxide 342 and the barrier layer 328 may be repeated m times to form a stack 348 of alternating layers, where m is an integer value greater than 1. N may represent a finite number of layers selected based on the targeted thickness and properties. The stack 348 of alternating layers may be considered as a rare-earth metal-containing oxide layer containing multiple alternating sub-layers.

The final structure shown in FIG. 3D is a cross sectional side view of an article 310 coated with a plasma resistant coating that comprises a surface high purity metal oxide layer 316 (e.g., an amorphous metal oxide) and a stack 348 of alternating layers of a rare earth metal-containing oxide 342 and a second oxide or other ceramic 328.

The second oxide or other ceramic may be a same oxide as an oxide used to form the surface layer (e.g., Al₂O₃) in some embodiments. Alternatively, the second oxide or ceramic may be a different oxide than the oxide used to form the surface layer.

Each layer of the rare earth metal-containing oxide may have a thickness of about 5-10 angstroms and may be formed by performing about 5 to about 10 cycles of an ALD process, where each cycle forms a nanolayer (or slightly less or more than a nanolayer) of the rare earth metal-containing oxide. In one embodiment, each layer of the rare-earth metal-containing oxide is formed using about 6 to about 8 ALD cycles. Each layer of the second oxide or other ceramic may be formed from a single ALD cycle (or a few ALD cycles) and may have a thickness of less than an atom to a few atoms. Layers of the rare earth metal-containing oxide may each have a thickness of about 5-100 angstroms, and layers of the second oxide may each have a thickness of about 1-20 angstroms in embodiments, and a thickness of 1-4 angstroms in further embodiments. The stack 348 of alternating layers of the rare earth metal-containing oxide 342 and the second oxide or other ceramic 328 may have a total thickness of about 5 nm to about 3 μm. The thin layers of the second oxide or other ceramic 346 between the layers 342 of the rare earth metal-containing oxide may prevent crystal formation in the rare earth metal-containing oxide layers. This may enable an amorphous yttria layer to be grown.

In the embodiments described with reference to FIGS. 3A-3D, the surface reactions (e.g., half-reactions) are done sequentially, and the various precursors and reactants are not in contact in embodiments. Prior to introduction of a new precursor or reactant, the chamber in which the ALD process takes place may be purged with an inert carrier gas (such as nitrogen or air) to remove any unreacted precursor and/or surface-precursor reaction byproducts. The precursors will be different for each layer and the second precursor for the yttrium-containing oxide layer or other rare-earth metal-containing oxide layer may be a mixture of two rare earth metal-containing oxide precursors to facilitate co-deposition of these compounds to form a single phase material layer. In some embodiments, at least two precursors are used, in other embodiments at least three precursors are used and in yet further embodiments at least four precursors are used.

ALD processes may be conducted at various temperatures depending on the type of process. The optimal temperature range for a particular ALD process is referred to as the “ALD temperature window.” Temperatures below the ALD temperature window may result in poor growth rates and non-ALD type deposition. Temperatures above the ALD temperature window may result in reactions taken place via a chemical vapor deposition (CVD) mechanism. The ALD temperature window may range from about 100° C. to about 400° C. In some embodiments, the ALD temperature window is from about 20° C. to about 200° C., or about 25° C. to about 150° C., or about 100° C. to about 120° C., or about 20° C. to 125° C. (e.g., when coating an insulator plate formed from a crosslinked polystyrene such as Rexolite®.

The ALD process allows for a conformal plasma resistant coating having uniform thickness on articles and surfaces having complex geometric shapes, holes with high aspect ratios (e.g., pores), and three-dimensional structures. Sufficient exposure time of each precursor to the surface enables the precursor to disperse and fully react with the surfaces in their entirety, including all of its three-dimensional complex features. The exposure time utilized to obtain conformal ALD in high aspect ratio structures is proportionate to the square of the aspect ratio and can be predicted using modeling techniques. Additionally, the ALD technique is advantageous over other commonly used coating techniques because it allows in-situ on demand material synthesis of a particular composition or formulation without a lengthy and difficult fabrication of source materials (such as powder feedstock and sintered targets). In some embodiments ALD is used to coat articles having aspect ratios of about 3:1 to 300:1.

With the ALD techniques described herein, multi-component films such as YₓAl_{y}O_{z} (e.g., Y_{3A15012}), YₓZr_{y}O_{z}, and YₐZrₓAl_{y}O_{z}, YₓEr_{y}O_{z}, YₓEr_{y}F_{z}, or Y_{w}ErₓO_{y}F_{z} can be grown, deposited or co-deposited, for example, by proper mixtures of the precursors used to grow the rare-earth metal-containing oxides alone or in combination with one or more other oxides as described above and in more detail in the examples below.

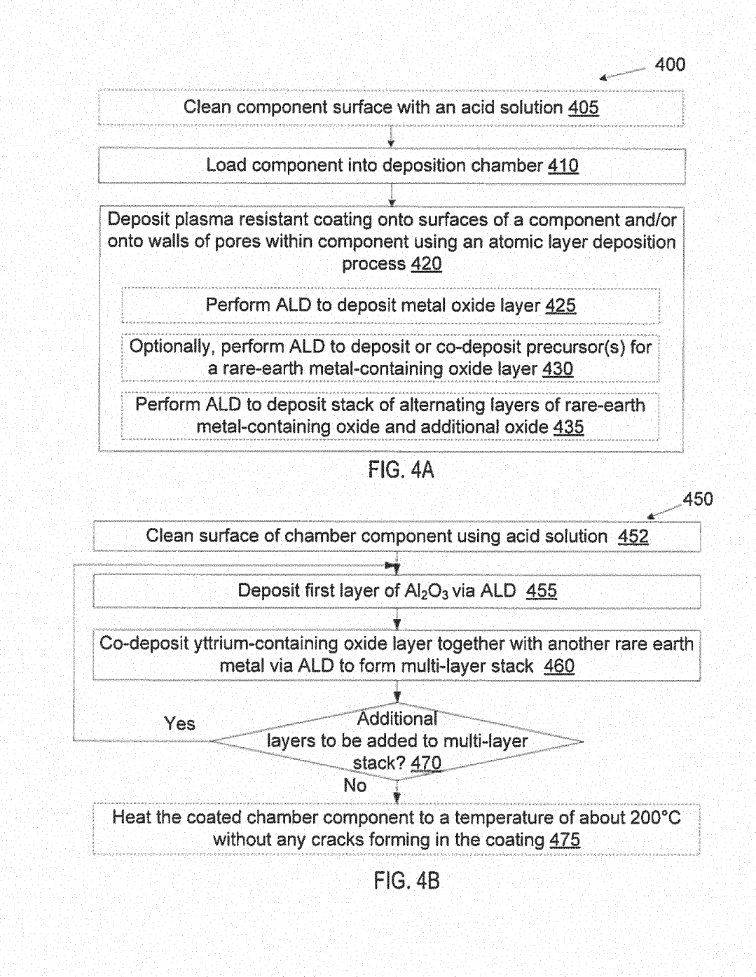

FIG. 4A illustrates a method 400 for forming a plasma resistant coating on a process chamber component (e.g., an insulator plate, an electrostatic puck, an ESC assembly, etc.) according to embodiments. Method 400 may be used to coat any articles described herein. The method may optionally begin by selecting a composition for the plasma resistant coating. The composition selection and method of forming may be performed by the same entity or by multiple entities.

The method may optionally include, at block 405, cleaning the article with an acid solution. In one embodiment, the article is bathed in a bath of the acid solution. The acid solution may be a hydrofluoric acid (HF) solution, a hydrochloric acid (HCl) solution, a nitric acid (HNO₃) solution, or combination thereof in embodiments. The acid solution may remove surface contaminants from the article and/or may remove an oxide from the surface of the article. Cleaning the article with the acid solution may improve a quality of a coating deposited using ALD. In one embodiment, an acid solution containing about 0.1 vol % to about 5.0 vol % HF is used to clean chamber components made of quartz. In one embodiment, an acid solution containing about 0.1 vol % to about 20 vol % HCl is used to clean articles made of Al₂O₃. In one embodiment, an acid solution containing about 5 to about 15 vol % HNO₃ is used to clean articles made of aluminum and other metals.

At block 410, the article is loaded into an ALD deposition chamber. At block 420, the method comprises depositing a plasma resistant coating onto a surface of the article using ALD. The plasma resistant coating is additionally deposited onto pore walls of pores within the article in some embodiments. In one embodiment, at block 425 ALD is performed to deposit a metal oxide layer such as an Al₂O₃ layer. The ALD may be performed at a relatively low deposition temperature of around 25-200° C. in embodiments to avoid damaging the component. Depending on the materials in the component, the ALD may be performed, for example, at temperatures of 30° C., 50° C., 80° C., 100° C., 125° C., 150° C., 180° C., and so on. In one embodiment, at block 430 ALD is optionally performed to deposit or co-deposit a rare-earth metal-containing oxide layer alone or together with one or more other oxides. ALD is a very conformal process as performed in embodiments, which may cause the surface roughness of the plasma resistant coating to match a surface roughness of an underlying surface of the article that is coated. The plasma resistant coating may have a total thickness of about 5 nm to about 3 μm in some embodiments. The plasma resistant coating may have a porosity of about 0% in embodiments, or may be porosity-free in embodiments, and may have a thickness variation of about ±5% or less, ±10% or less, or ±20% or less. The dielectric constant of the article with the plasma resistant coating may be the same or substantially the same (e.g., within ±5%) of the dielectric constant of the article without the coating.

In one embodiment, at block 435 ALD is performed to deposit a stack of alternating layers of a rare-earth metal containing oxide and an additional oxide. The additional oxide may be any of the oxides described herein. Alternatively, a single layer may be formed.

A yttrium-containing oxide layer includes a yttrium-containing oxide and may include one or more additional rare earth metal oxides. Rare earth meatal-containing oxide materials that include yttrium may be used to form the plasma resistant coating in embodiments because yttrium-containing oxides generally have high stability, high hardness, and superior erosion resistant properties. For example, Y₂O₃ is one of the most stable oxides and has a standard Gibbs free energy of formation)(ΔG_{f}°) of −1816.65 kJ/mol, indicating the reactions of Y₂O₃ with most of the process chemicals are thermodynamically unfavorable under standard conditions. Plasma resistant coatings that include a first metal oxide layer and rare-earth metal-containing oxide layer with Y₂O₃ deposited in accordance with embodiments herein may also have a low erosion rate to many plasma and chemistry environments, such as an erosion rate of about 0 μm/hr when exposed to a direct NF₃ plasma chemistry at a bias of 200 Watts and 500° C. For example, a 1 hour test of direct NF₃ plasma at 200 Watts and 500° C. caused no measureable erosion. Examples of yttrium-containing oxide compounds that the plasma resistant coating may be formed of include Y₂O₃, YₓAl_{y}O_{z} (e.g., Y₃Al₅O₁₂), YₓZr_{y}O_{z}, YₐZrₓAl_{y}O_{z}, or YₓEr_{y}O_{z}. The yttrium content in the plasma resistant coating may range from about 0.1 at. % to close to 100 at. %. For yttrium-containing oxides, the yttrium content may range from about 0.1 at. % to close to 100 at. % and the oxygen content may range from about 0.1 at. % to close to 100 at. %.

Examples of erbium-containing oxide compounds that the plasma resistant coating may be formed of include Er₂O₃, ErₓAl_{y}O_{z} (e.g., Er₃Al₅O₁₂), ErₓZr_{y}O_{z}, ErₐZrₓAl_{y}O_{z}, YₓEr_{y}O_{z}, and ErₐYₓZr_{y}O_{z} (e.g., a single phase solid solution of Y₂O₃, ZrO₂ and Er₂O₃). The erbium content in the plasma resistant coating may range from about 0.1 at. % to close to 100 at. %. For erbium-containing oxides, the erbium content may range from about 0.1 at. % to close to 100 at. % and the oxygen content may range from about 0.1 at. % to close to 100 at. %.

Advantageously, Y₂O₃ and Er₂O₃ are miscible. A single phase solid solution can be formed for any combination of Y₂O₃ and Er₂O₃. For example, a mixture of just over 0 mol % Er₂O₃ and just under 100 mol % Y₂O₃ may be combined and co-deposited to form a plasma resistant coating that is a single phase solid solution. Additionally, a mixture of just over 0 mol % E₂O₃ and just under 100 mol % Y₂O₃ may be combined to form a plasma resistant coating that is a single phase solid solution. Plasma resistant coatings of YₓEr_{y}O_{z} may contain between over 0 mol % to under 100 mol % Y₂O₃ and over 0 mol % to under 100 mol % Er₂O₃. Some notable examples include 90-99 mol % Y₂O₃ and 1-10 mol % Er₂O₃, 80-89 mol % Y₂O₃ and 11-20 mol % Er₂O₃, 70-79 mol % Y₂O₃ and 21-30 mol % Er₂O₃, 60-69 mol % Y₂O₃ and 31-40 mol % Er₂O₃, 50-59 mol % Y₂O₃ and 41-50 mol % Er₂O₃, 40-49 mol % Y₂O₃ and 51-60 mol % Er₂O₃, 30-39 mol % Y₂O₃ and 61-70 mol % Er₂O₃, 20-29 mol % Y₂O₃ and 71-80 mol % Er₂O₃, 10-19 mol % Y₂O₃ and 81-90 mol % Er₂O₃, and 1-10 mol % Y₂O₃ and 90-99 mol % Er₂O₃. The single phase solid solution of YₓEr_{y}O_{z} may have a monoclinic cubic state at temperatures below about 2330° C.

Advantageously, ZrO₂ may be combined with Y₂O₃ and Er₂O₃ to form a single phase solid solution containing a mixture of the ZrO₂, Y₂O₃ and Er₂O₃ (e.g., ErₐYₓZr_{y}O_{z}). The solid solution of YₐErₓZr_{y}O_{z} may have a cubic, hexagonal, tetragonal and/or cubic fluorite structure. The solid solution of YₐErₓZr_{y}O_{z} may contain over 0 mol % to 60 mol % ZrO₂, over 0 mol % to 99 mol % Er₂O₃, and over 0 mol % to 99 mol % Y₂O₃. Some notable amounts of ZrO₂ that may be used include 2 mol %, 5 mol %, 10 mol %, 15 mol %, 20 mol %, 30 mol %, 50 mol % and 60 mol %. Some notable amounts of Er₂O₃ and/or Y₂O₃ that may be used include 10 mol %, 20 mol %, 30 mol %, 40 mol %, 50 mol %, 60 mol %, 70 mol %, 80 mol %, and 90 mol %.

Plasma resistant coatings of YₐZrₓAl_{y}O_{z} may contain over 0% to 60 mol % ZrO₂, over 0 mol % to 99 mol % Y₂O₃, and over 0 mol % to 60 mol % Al₂O₃. Some notable amounts of ZrO₂ that may be used include 2 mol %, 5 mol %, 10 mol %, 15 mol %, 20 mol %, 30 mol %, 50 mol % and 60 mol %. Some notable amounts of Y₂O₃ that may be used include 10 mol %, 20 mol %, 30 mol %, 40 mol %, 50 mol %, 60 mol %, 70 mol %, 80 mol %, and 90 mol %. Some notable amounts of Al₂O₃ that may be used include 2 mol %, 5 mol %, 10 mol %, 20 mol %, 30 mol %, 40 mol %, 50 mol % and 60 mol %. In one example, the plasma resistant coating of YₐZrₓAl_{y}O_{z} contains 42 mol % Y₂O₃, 40 mol % ZrO₂ and 18 mol % Y₂O₃ and has a lamellar structure. In another example, the plasma resistant coating of YₐZrₓAl_{y}O_{z} contains 63 mol % Y₂O₃, 10 mol % ZrO₂ and 27 mol % Er₂O₃ and has a lamellar structure.

In embodiments, a plasma resistant coating that includes the surface layer and the rare-earth metal-containing oxide layer of Y₂O₃, YₓAl_{y}O_{z} (e.g., Y_{3A15012}), YₓZr_{y}O_{z}, YₐZrₓAl_{y}O_{z}, or YₓEr_{y}O_{z} has a low outgas sing rate, a dielectric breakdown voltage on the order of about 1000 V/μm, a hermiticity (leak rate) of less than about 1 E-8 Torr/s, a Vickers hardness of about 600 to about 950 or about 685, an adhesion of about 75 mN to about 100 mN or about 85 mN as measured by the scratch test and a film stress of about −1000 to −2000 MPa (e.g., about −1140 MPa) as measured by x-ray diffraction at room temperature.

In some embodiments, the plasma resistant coating may be formed from an aluminum oxide precursor selected from diethylaluminum ethoxide, tris(ethylmethylamido)aluminum, aluminum sec-butoxide, aluminum tribromide, aluminum trichloride, triethylaluminum, triisobutylaluminum, trimethylaluminum, or tris(diethylamido)aluminum for ALD.

In some embodiments, the plasma resistant coating is or includes yttria, and the yttrium oxide precursor used to form the rare-earth metal-containing oxide layer may be selected from or include tris(N,N-bis(trimethylsilyl)amide)yttrium (III) or yttrium (III)butoxide for the ALD.

In some embodiments the plasma resistant coating includes zirconium oxide. When the plasma resistant coating comprises zirconium oxide, a zirconium oxide precursor may include zirconium (IV) bromide, zirconium (IV) chloride, zirconium (IV) tert-butoxide, tetrakis(diethylamido)zirconium (IV), tetrakis(dimethylamido)zirconium (IV), or tetrakis(ethylmethylamido)zirconium (IV) for ALD. One or more of these zirconium oxide precursors may be co-deposited with a yttrium oxide precursor.

In some embodiments, the plasma resistant coating may further include an erbium oxide. An erbium oxide precursor may be selected from tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), or tris(butylcyclopentadienyl)erbium(III) for ALD.

FIG. 4B illustrates a method 450 for forming a plasma resistant coating on an article (e.g., an insulator plate, a ceramic electrostatic puck, an ESC assembly, etc.) according to an embodiment. The method may optionally begin by selecting compositions for the plasma resistant coating. The composition selection and method of forming may be performed by the same entity or by multiple entities.

At block 452 of method 450, a surface of the article (e.g., of the insulator plate, ceramic electrostatic puck, ESC assembly, etc.) is cleaned using an acid solution. The acid solution may be any of the acid solutions described above with reference to block 405 of method 400. The article may then be loaded into an ALD deposition chamber.

Pursuant to block 455, the method comprises depositing a first layer of amorphous HP-Al₂O₃ onto surfaces of the article via ALD (including on pore walls of pores within the article). The amorphous HP-Al₂O₃ may have a thickness of about 5 nm to about 300 nm. Pursuant to block 460, the method further comprises forming a second layer by co-depositing (i.e., in one step) a mixture of a yttrium-containing oxide precursor and another oxide precursor onto the amorphous HP-Al₂O₃ surface layer via ALD. The second layer may include Y₂O₃ in a single phase with Al₂O₃ or Er₂O₃ or ZrO₂, for example. Alternatively, the second layer may include multiple phases, such as a phase of Y₄Al₂O₉ and another phase comprising a solid-solution of Y₂O₃—ZrO₂.

As discussed above, the rare-earth metal-containing oxide layer may include a mixture of multiple different oxides. To form such a rare-earth metal-containing oxide layer, any combination of the aforementioned yttria precursors, erbium oxide precursors, alumina precursors and/or zirconium oxide precursors may be introduced together into an ALD deposition chamber to co-deposit the various oxides and form a layer having a single phase or multiple phases. The ALD deposition or co-deposition may be performed in the presence of ozone, water, O-radicals, or other precursors that may function as oxygen donors.

At block 470, a determination may be made as to whether additional layers are to be added (e.g., if a multi-layer stack is to be formed). If additional layers are to be added, then the method may return to block 455 and an additional layer of Al₂O₃ may be formed. Otherwise the method may proceed to block 475.

At block 475, the article (e.g., the insulator plate, ceramic electrostatic puck, ESC assembly, etc.) and both layers of the plasma resistant coating on the chamber component are heated. The heating may be via an annealing process, a thermal cycling process and/or via a manufacturing step during semiconductor processing. In one embodiment, the thermal cycling process is performed on coupons as a check after manufacture to detect cracks for quality control, where the coupons are cycled to the highest temperature that a part may experience during processing. The thermal cycling temperature depends on a specific application or applications that the part will be used for. For an insulator plate, a ceramic electrostatic puck, an ESC assembly of a substrate assembly, for example (shown in FIGS. 2A-2B), coupons may be cycled between room temperature and 250° C. The temperature may be selected based on the material of construction of the article, surface, and film layers so as to maintain their integrity and refrain from deforming, decomposing, or melting any or all of these components.

Methods 400 and 450 may be performed on a single component or on a batch of multiple components. The multiple components may be the same type of component or may be different types of components. For example, a batch may include an insulator plate and an electrostatic puck. Methods 400 and 450 may also be performed on assembled electrostatic chuck assemblies and/or assembled substrate support assemblies (or portions thereof). If method 400 or 450 is to be performed to apply a plasma resistant coating to an assembled electrostatic chuck assembly or substrate support assembly, then the method may be preceded by one or more assembly operations. Such assembly operations may include bonding the electrostatic puck to the cooling plate and/or placing an o-ring around the electrostatic puck and cooling plate interface, for example.

The following examples are set forth to assist in understanding the embodiments described herein and should not be construed as specifically limiting the embodiments described and claimed herein. Such variations, including the substitution of all equivalents now known or later developed, which would be within the purview of those skilled in the art, and changes in formulation or minor changes in experimental design, are to be considered to fall within the scope of the embodiments incorporated herein. These examples may be achieved by performing method 300 or method 350 described above.

### Example 1—Etch Rate Performance of Coated and Uncoated Polymer Substrates

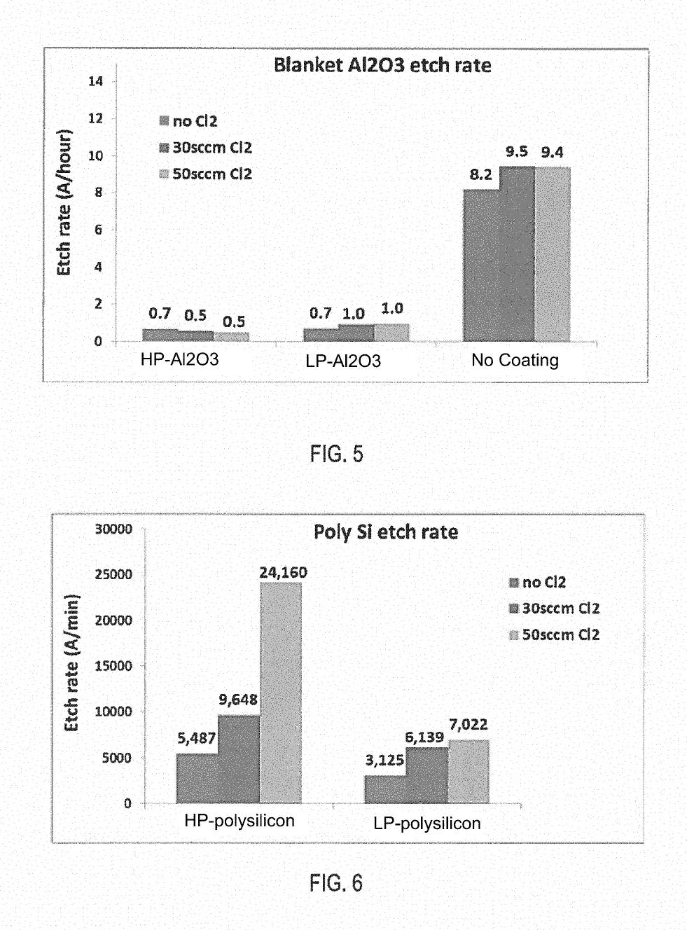

FIG. 5 is a chart showing the etch rate of ALD Al₂O₃ coatings on a substrate when exposed to fluorine chemistry. Each of three separate sample types were exposed to fluorine chemistry together with varying amounts of chlorine (Cl₂) gas (no Cl₂, 30 sccm Cl₂ and 50 sccm Cl₂). The samples with a high purity Al₂O₃ coating had a relatively low etch rate of less than 1 Å/hour. The addition of Cl₂ may have slightly lowered (or did not have an appreciable effect on) the etch rate of the HP-Al₂O₃ coatings. The samples with a low purity (LP)-Al₂O₃ coating had an etch rate of 1 Å/hour or less. The addition of Cl₂ may have slightly increased (or did not have an appreciable effect on) the etch rate of the LP-Al₂O₃ coatings. The samples without a coating had relatively high etch rates of greater than 8 Å/hour.

### Example 2—Etch Rate Performance of Coated and Uncoated Polymer Substrates

FIG. 6 is a chart showing the etch rate of a polysilicon coated substrate when exposed to a fluorine chemistry. Each of two separate sample types were exposed to fluorine chemistry together with varying amounts of chlorine (Cl₂) gas (no Cl₂, 30 sccm Cl₂ and 50 sccm Cl₂). The samples with a high purity (HP) polysilicon coating had a relatively high etch rate of greater than 5,400 Å/hour. The addition of Cl₂ significantly increased the etch rate of the HP polysilicon coatings. The samples with a low purity (LP) polysilicon coating had an etch rate of greater than 3,100 Å/hour. The addition of Cl₂ increased the etch rate of the LP polysilicon coatings.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. An article comprising:
a component comprising an insulator material with a dielectric constant of about 1.0 to about 10.0; and
a plasma resistant coating on a surface of the insulator material, the plasma resistant coating having a thickness of about 5 nm to about 10 μm,
wherein the plasma resistant coating protects the insulator material from erosion, and
wherein the insulator material with the plasma resistant coating has the dielectric constant or an adjusted dielectric constant that is within about ±5% of the dielectric constant of the insulator material without the plasma resistant coating.

2. The article of claim 1, wherein the article is a substrate support assembly and the component is an insulator plate of the substrate support assembly.

3. The article of claim 2, wherein the insulator plate comprises a material selected from a group consisting of a crosslinked polystyrene, a polytetrafluoroethylene and an aluminum oxide, and wherein the plasma resistant coating further protects the insulator plate from ultraviolet radiation.

4. The article of claim 3, wherein the insulator plate comprises crosslinked polystyrene and has a thickness of about 0.5 inch to about 1.5 inch.

5. The article of claim 1, wherein the article is a substrate support assembly and the component is an electrostatic puck of the substrate support assembly.

6. The article of claim 5, wherein the substrate support assembly further comprises:
a cooling base bonded to the electrostatic puck; and
a porous plug disposed in a hole in the electrostatic puck;
wherein the plasma resistant coating covers exposed portions of the substrate support assembly, including exposed portions of the electrostatic puck, the cooling base and the porous plug, and wherein the plasma resistant coating further covers walls of pores within the porous plug.

7. The article of claim 5, wherein the electrostatic puck comprises a material selected from a group consisting of a ceramic, a metal-ceramic composite, a metal, a polymer, a polymer ceramic composite, mylar and polyester, wherein the ceramic is further selected from a group consisting of a two phase Al₂O₃/SiO₂ based material, a two phase Al₂O₃/Al₃SiO₂ based material, a three phase Al₂O₃/MgO/SiO₂ based material, a two phase AlN/SiO₂ based material, Al₂O₃, or AN.

8. The article of claim 1, wherein the plasma resistant coating consists essentially of aluminum oxide.

9. The article of claim 1, wherein the plasma resistant coating comprises at least one of yttrium oxide or erbium oxide.

10. The article of claim 1, wherein the plasma resistant coating comprises:
a metal oxide layer; and
a rare earth metal-containing oxide layer, the rare earth metal-containing oxide layer comprising a material selected from a group consisting of Y₂O₃, Y₃Al₅O₁₂ (YAG), ZrO₂, Gd₂O₃, a solid solution of Y₂O₃—ZrO₂, and a ceramic compound comprising Y₄Al₂O₉ and a solid-solution of Y₂O₃—ZrO₂.

11. A method comprising:
performing atomic layer deposition (ALD) to deposit a plasma resistant coating on a component comprising an insulator material with a dielectric constant of about 1.0 to about 10.0,
wherein the plasma resistant coating has a thickness of about 50 nm to about 5 μm,
wherein the plasma resistant coating protects the insulator material from erosion, and
wherein the insulator material with the plasma resistant coating has the dielectric constant or an adjusted dielectric constant that is within about ±5% of the dielectric constant of the insulator material without the plasma resistant coating.

12. The method of claim 11, wherein the component is an insulator plate for a substrate support assembly.

13. The method of claim 12 wherein the insulator plate comprises a material selected from a group consisting of a crosslinked polystyrene, a polytetrafluoroethylene and an aluminum oxide, and wherein the plasma resistant coating further protects the insulator plate from ultraviolet radiation.

14. The method of claim 13, wherein the insulator plate comprises crosslinked polystyrene and has a thickness of about 0.5 inch to about 1.5 inch.

15. The method of claim 11, wherein the component is an electrostatic puck that comprises a material selected from a group consisting of a ceramic, a metal-ceramic composite, a metal, a polymer, a polymer ceramic composite, mylar and polyester, wherein the ceramic is further selected from a group consisting of a two phase Al₂O₃/SiO₂ based material, a two phase Al₂O₃/Al₃SiO₂ based material, a three phase Al₂O₃/MgO/SiO₂ based material, a two phase AlN/SiO₂ based material, Al₂O₃, or AN.

16. The method of claim 11, wherein the ALD is performed at a temperature of about 25° C. to about 200° C.

18. The method of claim 11, wherein the component is a substrate support assembly comprising an electrostatic puck, a cooling base, an o-ring and a porous plug, the method further comprising:
assembling the substrate support assembly prior to performing the ALD, wherein the plasma resistant coating covers exposed portions of the electrostatic puck, the porous plug, the o-ring and the cooling base.

19. A substrate support assembly comprising:
an electrostatic puck comprising at least one through hole that extends from a top surface of the electrostatic puck to a bottom surface of the electrostatic puck, wherein the electrostatic puck has a first dielectric constant of about 1.0 to about 10.0;
a porous plug in the at least one through hole;
a cooling base bonded to the bottom surface of the electrostatic puck by a bond; and
a first plasma resistant coating covering exposed surfaces of the electrostatic puck, the porous plug and the cooling base without covering unexposed portions of the electrostatic puck and the cooling base;
wherein the first plasma resistant coating protects the substrate support assembly from erosion, and
wherein the electrostatic puck with the first plasma resistant coating has the first dielectric constant or a first adjusted dielectric constant that is within about ±5% of the dielectric constant of the electrostatic puck without the first plasma resistant coating.

20. The substrate support assembly of claim 19, further comprising:
a facilities plate secured to a bottom surface of the cooling base;
an insulator plate secured to a bottom surface of the facilities plate, the insulator plate having a second dielectric constant of about 1.0 to about 10.0;
an o-ring at an interface of the electrostatic puck and the cooling base, wherein at least a portion of the o-ring is coated with the first plasma resistant coating; and
a second plasma resistant coating that covers at least a portion of the insulator plate, wherein the second plasma resistant coating has a thickness of about 5 nm to about 10 μm,
wherein the second plasma resistant coating protects the insulator plate from erosion and from ultraviolet radiation, and
wherein the insulator plate with the second plasma resistant coating has the second dielectric constant or a second adjusted dielectric constant that is within about ±5% of the second dielectric constant of the insulator plate without the additional plasma resistant coating.
